(19) United States
(12) Patent Application Publication
(10) Pub. No.: US 2013/0224901 A1
(43) Pub. Date: Aug. 29, 2013

(54) Production Line to Fabricate CIGS Thin Film Solar Cells via Roll-to-Roll Processes

(71) Applicant: Jiaxiong Wang, Danville, CA (US)

(72) Inventor: Jiaxiong Wang, Danville, CA (US)

(21) Appl. No.: 13/405,304

(22) Filed: Feb. 26, 2012

(51) Int. Cl. H01L 31/18; B05C 11/00

(52) U.S. Cl. 438/95; 118/35; 257/E31.004

(57) ABSTRACT

An industrial production line is presented to fabricate CIGS thin film solar cells on continuous flexible substrates in roll-to-roll processes. It provides an entire solution including procedures and related equipments from starting blank substrates to completed solar cells that can be used to fabricate solar modules. This production line contains some core apparatuses, such as a modular electroplating system to deposit CIGS materials, a modular thermal reactor to annealing the CIGS films, and a chemical bath deposition reactor to coat CdS buffer layer, are recently invented by the present inventor. The present production line can be conveniently used to prepare the CIGS thin film solar cells with high efficiency but low cost.

### FIELD OF THE INVENTION

The present invention presents a production line to fabricate CIGS thin film solar cells via roll-to-roll or reel-to reel processes. This production line contains preparation methods from a starting flexible substrate to completed CIGS solar cells and a series of related roll-to-roll equipments. Some core equipments involved in this production line were invented by the present inventor.

### BACKGROUND

Photovoltaic technology has recently attracted increasing interest as a source of renewable energy under a background of global warming and exhausting of fossil fuels. The first generation photovoltaic devices, i.e., single crystal and multi-crystal silicon solar cells, have been commercially developed for more than a half century. At present, the silicon solar cells occupy almost 90% of global photovoltaic market demand. As their potential competitors, however, thin film solar cells have been developed to industrial manufacture scales due to their cost arguments, flexibility and favorable superior energy balance. The main types of thin film solar cells include amorphous silicon, CIGS and CdTe. In this thin film solar cell family, CIGS solar cells possess the highest conversion efficiency that is as high as 20.3%. In a periodic table of the elements, the elements of a CIGS absorber are located in Group IB-IIIA-VIA. These absorber materials belong to multi-component p-type direct gap semiconductors. For such a semiconductor material, the distribution of different components and stoichiometry may determine the quality of the material.

A CIGS solar cell contains a stack of absorber/buffer thin film layers to create an efficient photovoltaic heterojunction. A transparent conductive metal oxide window containing a highly resistive layer, which has a band gap to transmit the sunlight to the absorber/buffer interface, and a lowly resistive layer to minimize resistive losses and provide electric contacts, is deposited onto the absorber/buffer surface. This kind of design significantly reduces charge carrier recombination in the window layer and/or in the window/buffer interface because most of the charge carrier generation and separation are localized within the absorber layer. In general, CIGS solar cell is a typical case in Group IB-IIIA-VIA compound semiconductors comprising some of Group IB (Cu, Ag, Au), Group IIIA (B, Al, Ga, In, Tl) and Group VIA (O, S, Se, Te, Po) elements of the periodic table. These elements are excellent absorber materials for thin film solar cells. In particular, compounds containing Cu, In, Ga, Se and S are generally referred to as CIGS(S), or Cu(In,Ga)(S,Se)₂ or CuIn₁₋ₓGaₓ (S_{y}Se_{1-y}), where 0≦x≦1, 0≦y≦1 and n is approximately 2, and have already been applied in the solar cell structures that gave rise to conversion efficiencies over 20%. Here, Cu(In,Ga)(S,Se)₂ means the whole family of compounds with Ga/(Ga+In) molar ratio varying from 0 to 1, and Se/(Se+S) molar ratio varying from 0 to 1. It should be noted that the molar ratios of Ga/(Ga+In) and Cu/(Ga+In) are very important factors to determine the compositions and the conversion efficiencies of CIGS solar cells. In general, a good CIGS solar cell requires a ratio of Cu/(Ga+In) between 0.75 and 0.95, and Ga/(Ga+In) between 0.3 and 0.6.

The preparations of CIGS thin film solar cells and their modules have to undergo a series of complicated processes. In a roll-to-roll or reel-to-reel process, for example, a roll of flexible substrate has to go through multiple coating and reaction processes, such as surface cleaning, back contact coating, coating and reaction of a CIGS absorber layer, CdS buffer layer preparation, coating of transparent conductive oxides (TCO) window layers, and preparation of finger and bus lines, to become solar cells. After these steps, a completed solar cell roll has to be cut into single solar cells that will be measured and sorted according to different conversion efficiencies and other parameters. The production line consists of a series of roll-to-roll equipments to complete the thin film solar cell preparation. These equipments may include a cleaner, a coating machine to prepare the back contact layer, an apparatus to deposit the CIGS absorber layer, a thermal reactor to anneal the CIGS material, a coating apparatus to prepare the CdS buffer layer, a coating machine for deposition of the TCO window layers, an equipment to prepare the finger and bus lines, and a system to cut the roll into the single cells and then measure them for sorting. These equipments may be in a continuous line or independent.

There are some different technologies to fabricate the CIGS solar cells. A typical system is on the basis of vacuum coating, such as sputtering and evaporation. In addition to the vacuum ways, some wet coating methods and related equipments can also be used in deposition of some core layers. For example, a print or an electroplating method can be applied to deposit the CIGS layer and a chemical bath deposition (CBD) may be used to prepare the CdS layer.

The present invention provides an entire production line containing methods and some core equipments to fabricate CIGS thin film solar cells from the substrates to the completed solar cells via roll-to-roll or reel-to-reel processes. Several important equipments and the methods to prepare some core component layers in this production line are described in other patent applications which are submitted by the present inventor and included in this invention as references. These inventions include a patent application with a number of Ser. No. 13/046,710 for electroplating Cu/In/Ga (CIG)/(S) multiple layers, a patent application with a number of Ser. No. 13/084,568 for annealing CIGS materials, and a patent application with a publication number of US 2011/0256656 A1 for depositing CdS layer with a chemical bath deposition (CBD) method. These three core equipments and the related methods comprise the most important parts in the whole production line.

With the present production line, a roll of flexible substrate is firstly cleaned through a roll-to-roll ultrasonic cleaner and dried. The cleaned substrate is delivered into a roll-to-toll sputter to deposit a molybdenum layer as a back contact and other additional metal layers for electroplating application. The substrate then passes an electroplating system patented with an application number of Ser. No. 13/046,710 to deposit copper, gallium and indium multiple layers on the top of the back contact layer. Selenium is evaporated onto the substrate surface from a roll-to-roll vacuum evaporator to constitute all of the components of a CIGS absorber. The substrate is then delivered into a vacuum thermal reactor patented with a number of Ser. No. 13/084,568 to anneal the CIGS absorber layer. The CdS buffer layer is deposited onto the surface of CIGS layer from a CBD reactor patented with a publication number of US 2011/0256656 A1. The substrate roll is then transferred into a roll-to-roll sputter to coat ZnO₂/ITO (i.e., tin doped indium oxide) or ZnO₂/AZO (i.e., aluminum doped zinc oxide) window layers. The finger and bus lines are screen-printed onto the window surface through a roll-to-roll screen printer. This completed roll is then cut into designed small solar cell pieces, followed by the parameter measurements with a solar simulator equipped measurement system and then sorted into different groups according to their measured conversion efficiencies.

The CIGS thin film solar cell production line presented here consists of a series of equipments and the related preparation methods to fabricate CIGS solar cells in roll-to-roll or reel-to-reel processes. It provides a full solution to produce the CIGS solar cells on flexible substrates. With an electroplating method to prepare the CIG layer, the preparation cost for the entire process is much lower than a vacuum method does. This makes the resultant solar cells possess superior competitiveness to the silicon solar cells. In addition, some core equipments involved in this invention are invented by the present inventor with good qualities and inexpensive costs, such as the CdS reactor. This production line can produce over 30 MW solar cells per year if one meter wide flexible substrate rolls are used on the basis of one meter per minute substrate delivery speed.

### SUMMARY OF THE INVENTION

The present invention provides a roll-to-roll or reel-to-reel CIGS thin film solar cell production line which is made up of a series of equipments and related preparation methods. This production line contains some core equipments, i.e. a modular electroplating apparatus to deposit the CIG layers, a vacuum thermal reactor to anneal the CIGS absorber, and a unique CBD reactor to coat CdS layer, all of which are newly submitted patent applications. The production line also involves other common vacuum apparatuses such as sputters and an evaporator. Because an electroplating method is used to deposit the CIG layers, however, the final cost to manufacture the CIGS solar cells is much less expensive than a vacuum-only process does. The other apparatuses such as a CBD reactor are also designed with low fabrication costs and high working qualities. With one present production line, the CIGS thin film solar cells can be manufactured with a power capacity as high as 30 MW per year if it is designed to run one meter wide flexible substrates with a substrate delivery speed of one meter per minute.

### BRIEF DESCRIPTION OF THE DRAWINGS

FIG. 1 shows a structure diagram of a completed CIGS thin film solar cell prepared with the present production line.

FIG. 2 shows a modular segment in the apparatus to electroplate CIGS absorber layers onto a flexible conductive substrate through a roll-to-roll process.

FIG. 3 illustrates an apparatus with two modular buffer segments in the center for reaction of a precursor layer coated on a flexible foil substrate to fabricate an absorber layer in a CIGS solar cell with a roll-to-roll process.

FIG. 4 shows a front view of a CBD reactor to deposit CdS layers with a continuous flexible workpiece through a roll-to-roll process.

FIG. 5 shows a top view of a CBD reactor to deposit CdS layers with a continuous flexible workpiece through a roll-to-roll process.

### DETAILED DESCRIPTION OF THE INVENTION

The present invention provides a production line comprising a series of apparatuses and related methods for manufacturing CIGS thin film solar cells via roll-to-roll or reel-to-reel processes. With the present invention, a manufacture process starts from a roll of flexible substrate that may be conductive materials such as stainless steel or aluminum foils, or nonconductive materials such as polymer foils. Conductivity of the substrate may significantly affect the entire manufacture process. For a nonconductive substrate, for example, the top electrodes can be achieved through several scribe steps rather than printing finger and bus lines. At present, the common substrates used are still conductive metal foils. Therefore, a conductive metal foil such as a stainless steel has been used as examples in the present invention.

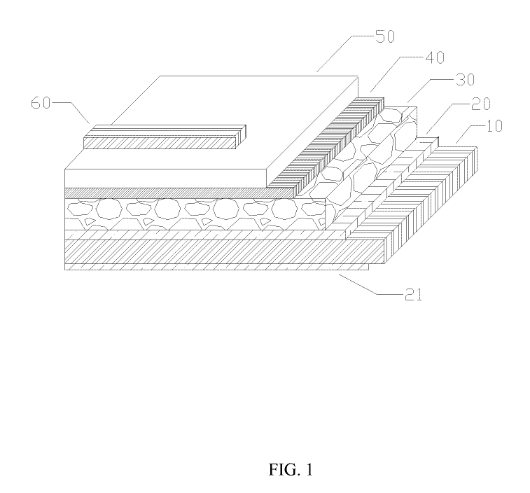

FIG. 1 shows a schematic structure diagram of a CIGS thin film solar cell prepared using the present production line. The flexible substrate is marked as 10. Above this substrate, is coated with a back contact layer 20 that is actually comprised of several metal layers. Another inert metal layer 21 is deposited on the backside of the substrate to prevent any ion escaping out of the substrate. On the surface of the layer 20, a CIGS semiconductor layer 30 is deposited. Above it, a CdS buffer layer 40 is coated. A p-n junction will be formed at the interface of the layers 30 and 40. A TCO window layer 50 is coated above the CdS layer. On the top of the cell, there are some finger and bus lines as numbered as 60.

In order to successfully fabricate the solar cell shown in FIG. 1 with the present production line, one has to deposit the different layers step by step from the bottom layers 20 and 21 to the top layer 60 according to the manufacture procedures and the related apparatuses described below.

Step 1: Cleaning of a substrate roll.

A qualified substrate roll shall be cleaned before further processing. The substrate will be continuously delivered through a cleaner that possesses an ultrasonic power. The substrate shall be ultrasonically cleaned with a heated detergent solution and ultrasonically rinsed with de-ionized (DI) water. After dried, the cleaned roll will be transferred to the second step to deposit the back contact layers.

Step 2: Coating of back contact and accessory layers.

If a substrate roll is made from a kind of nonconductive material, a metal layer such as molybdenum (Mo) has to be coated onto the cleaned substrate surface as a back contact layer. If the substrate is a conductive material such as stainless steel or aluminum foil, the Mo layer is still necessary to be coated onto the substrate surface. The Mo layer can effectively block the ions from the substrate immigrating into the CIGS semiconductor layer. Thickness of the Mo layer may be a few hundreds of nanometers. The best method to deposit Mo in the present invention is sputtering. Although the electroplating of CIG(S) layers can be directly carried out on the Mo surface, the electroplating is usually very difficult to be conducted directly on the Mo surface. If a substrate is a kind of smooth glass plate, the electroplating on the Mo surface may be successful. If it is a flexible conductive metal foil, however, the electroplating of CIG(S) layers directly on the Mo surface may meet an adhesion problem, probably because there are many micro-defects on a metal foil surface. As a result, a thin accessory metal layer may have to be sputtered onto the Mo surface to improve the adhesion and nucleation between the Mo and CIG(S) layers.

Such a kind of accessory metal layer has been presented in some previous invention. For example, a US patent with a number of U.S. Pat. No. 8,008,113 B2 describes to use some metals such as ruthenium (Ru), iridium (Ir), tungsten (W) or their nitride as an accessory metal layer to improve nucleation and adhesion. However, some metal like Ru is a very expensive. Its application significantly increases costs of the solar cells, which affects competitiveness of the resultant solar cells. Therefore, a cheap metal or other solutions should be found out to reduce the costs. One solution in the present invention is to use a cheap metal such as niobium (Nb). Some experimental results indicate that Nb can significantly improve the adhesion between the CIG(S) and the Mo layers. In the following annealing reaction of the CIGS layer, the annealed CIGS layers are still tightly attached to the substrate surfaces.

A roll-to-roll sputter used in this step does not require any special design. However, it requires multiple targets to sputter different layers. For a thick film like Mo, more than one targets are necessary to meet a requirement of delivery speed such as one or two meters per minute. Preferably, 6-12 targets are required to be equipped inside the sputtering chambers. Among them, 2-4 targets shall be arranged to sputter the metal layers on the back of the substrate for a protection reason. The sputter can be designed with a vertically delivered substrate or a horizontally delivered one. In addition, uniformity of the sputtered layers is required. Therefore, a sputter should be able to deposit uniform and high quality multiple metal layers. The completed substrate roll can be transferred to the next step for electroplating.

Step 3: Electroplating of the CIG or CIGS layers.

It is the most important step to deposit CIG or CIGS multiple layers on the top of the back contact layer. As a core component, the CIGS layer determines the quality of the resultant solar cells. In the present production line, an electroplating method is used to deposit the CIG or CIGS multiple layers. The modular electroplating apparatus and the related method has been described in another US patent application with a number of Ser. No. 13/046,710. This modular electroplating apparatus features multiple assembled plating sections which allow different plating baths to be used for deposition of multiple layers with changeable plating orders. With this kind of design, copper (Cu), indium (In), gallium (Ga) and/or selenium (se) mono-layers can be deposited layer by layer with different orders. The CIG or CIGS layers can also been deposited from some alloy solutions containing two or more components of Cu, In, Ga and/or Se, combined with single element layers.

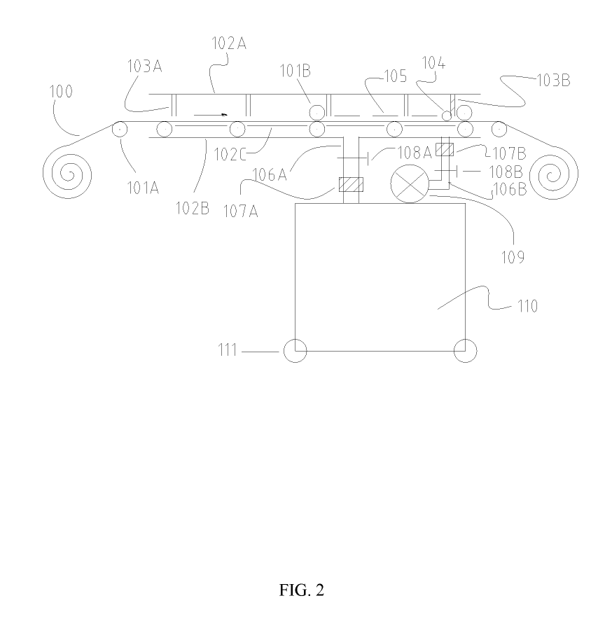

FIG. 2 shows one of the modular segments in a production line. The whole apparatus can be assembled with multiple modular segments. Between every two modular sections, one washing segment shall be inserted. This washing section contains nozzles to wash both sides of the flexible substrates to make sure that a clean surface is brought into the next electroplating modular section. There are also some electrically conductive rollers or brushes fixed inside the washing sections to conduct current. At the end of electrodeposition, the substrate will be washed and dried.

As shown in FIG. 2, the flexible conductive substrate 100 is delivered into a modular electroplating section from left to right along the arrow direction. The rollers 101A are arranged under the substrate to support it and the soft rollers 101B are on the top of the substrate just outside of the top plating cell to avoid the electrolyte solution flowing out without damaging the plated layers. 102A and 102B represent the top edge and the bottom of the modulae segment. 102C is the bottom of the plating cell. It is half to a few centimeters under the substrate 100. 103B is a fixed right edge of the top plating cell. 103A stands for several pairs of grooves on the both walls of the modular section above the substrate 100. Between a pair of grooves, a board can be tightly inserted to hold the solution inside the top plating cell between 103B and this 103A. By placing this isolating board to the other pairs of grooves, one can adjust the length of the top plating cell to meet the requirement of the applied current densities. Inside the top electroplating cell, the net anode modules 105 can be fixed parallel above the flexible substrate. A longer top plating cell requires more anode modules. These chemical resistant net anode modules are porous to allow the gas escaping from the plating baths. There is a pipe 104 with a dead end on one side and some small holes on the body. The other open end of this pipe is connected to the pipe 106B through a quick connecting adaptor 107B. The electrolyte solution shall be delivered with the pump 109 from the solution tank 110 to the pipe 104, and then flowing back to the tank through the pipe 106A. The diameters, density and arrangement of the holes in the pipe 104 shall be carefully designed to meet the requirements of electroplating hydrodynamics. Two valves 108A and 108B are used along with the pump 109 to hold enough solution inside the top plating cell. A filter (not shown in FIG. 1) can be connected between the valve 108B and the pump 109 or another location to filter the plating solution. The solution tank 110 may be easily disconnected from this modular segment with the quick connecting adaptors 107A and 107B and moved away through four wheels 111 installed under the bottom of the tank.

With this electroplating apparatus, Cu, In, Ga and/or Se monolayers or their alloy multiple element layers can be plated with various combinations to obtain uniform and stoichiometric defect-free CIG or CIGS multi-layers. As a semiconductor material, selenium may be difficult to be plated underneath the other metal layers due to its extremely low electrochemical potential. Although Se can be deposited as a top layer, its thickness and quality may be limited by its poor conductivity. Therefore, it may be better to evaporate Se onto the electroplated CIG(S) layers as shown in Step 4. Because this electroplating apparatus is flexible for different electroplating baths, different solutions can be developed to plate layers with single or multiple elements.

Step 4: Evaporation of selenium.

Selenium can be deposited onto the electroplated CIG or CIGS layers to provide stoichiometric CIGS components. An evaporation method is included in the present production line. Although the evaporator does not require special designs, the evaporation crucibles should have a rectangle geometric shape matched with width of the substrate rolls to improve the uniformity of an evaporated Se film. In addition, the vacuum level shall reach 10⁻⁶-10⁻⁵ torr. At this vacuum level, a mean free path of the evaporated Se atoms possesses the same order as the equipment dimension to maintain the uniformity of the evaporated films.

In addition to Se, some amount of dopant such as a salt of sodium, potassium or lithium has to be doped into the CIGS layer through the thermal evaporation procedures. The doped amount is about 1% of the CIGS weight. Because these dopants usually require higher temperatures than Se does, the evaporator should be capable of heating up to about 1,000° C.

The heating method of an evaporator can be designed on the basis of a crucible's resistivity. Although an electron beam method may be more efficient, a resistive heating method is simpler and inexpensive.

Step 5: Thermal reaction to anneal the CIGS layer.

At the beginning of this step, all of the CIGS components have been deposited on the substrate surface. These multiple CIGS layers have to pass an annealing reaction to become a homogeneous CIGS absorber layer with a stoichiometric ratio. After this annealing reaction, the resultant CIGS absorber layer should be homogeneous with the same CIGS ratio over the substrate and without significant defects. This annealing reaction is usually conducted with a rapid thermal process (RTP). The material is firstly rapidly heated up to a temperature between 500 and 600° C. under an inert atmosphere. Then it shall be held under a constant reaction temperature for a certain period to let the different components mix well through a thermal diffusion. During this period, the excess Se will be evaporated and the material becomes stoichiometric. Although the mechanism of this reaction is simple, the conditions have to be controlled very strictly. For example, the inert atmosphere should be very pure to avoid a material oxidation, and the temperature should be precisely controlled to avoid non-uniform crystalline distribution.

A vacuum tight roll-to-roll thermal reactor invented by the present inventor has been submitted with an application number of Ser. No. 13/084,568 to meet the requirements described above. A substrate roll to be reacted is firstly loaded into the reactor, followed by several vacuum-inert gas cycles to remove any reactive residues. Then the substrate is delivered into the reaction chambers after they are heated to a constant reaction temperature. These reaction chambers are constituted from a series of modular segments. The number of the modular segments are determined by the reaction time. Fluctuation of the temperatures inside the reactor is controlled to be less than 2° C. The evaporated excess Se is led to a collector outside the reaction chambers. With this reactor, a homogeneous CIGS semiconductor absorber layer can be obtained.

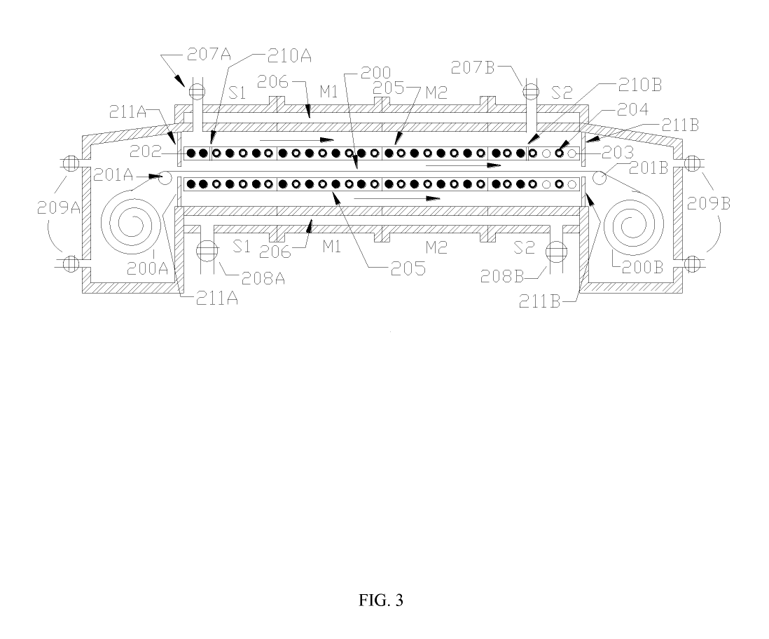

FIG. 3 shows an apparatus with a combination of the roll unwinding chamber plus the heating section S1, two modular buffer segments M1 and M2 in series, and the cooling section S2 plus the roll winding chamber. The flexible substrate roll 200 is delivered from the unwinding chamber (200A), through the rollers 201A and 201B, to the winding chamber (200B) along the arrow direction with a certain speed. The unwinding chamber is directly connected to the heating section S1 where the substrate is quickly heated up to a constant annealing or reaction temperature with a RTP process. Then the substrate goes through the annealing/reaction oven that is constituted with a series of thermal control components in modular buffer segments M1, M2 . . . before it passes the cooling section S2 that is directly connected to the winding chamber. The cooling elements in S2 may be constituted from some stainless steel tubing loaded with cold water or a cold inert gas. The whole annealing/reaction oven 205 expended from S1 to S2 may be fabricated from the materials of graphite, ceramic or quartz crystal. The heating elements 202 and the cooling elements 203 can be installed inside a thermal control component or arranged above and underneath it, combined with the thermocouples 204. The heating and the cooling elements combined with the thermocouples are densely arranged along this thermal control component to guarantee that the whole precursor film on the flexible substrate 200 is annealed or reacted at a constant temperature ±1° C.

Before the RTP and the reaction start, the substrate roll 200 is loaded in the reactor. The whole system is then carried out at least three cycles of vacuum-inert gas to remove any impurity from the apparatus. During these cycles, the volves 207A and 207B are closed, and 209A and 209B are opened. One of the volves 209A and one of 209B are used as the vacuum outlets and the rest two as the inert gas inlets. The present apparatus is designed to obtain a high vacuum down to 10⁻³ Pa. When the system is ready, the annealing/reaction oven 205 starts to heat the temperature up to a certain degree. During this process, the volve 208A and/or 208B are opened to a vacuum system. Then the roll 200A starts to move along the arrow direction and the gas volve 207A and 207B are opened to introduce the inert or reaction gas into 207A and out of 207B if the annealing or the reaction is not conducted under a vacuum. The gas can penetrate the hole inlet 210A and escape out of the hole outlet 210B before it reaches the cooling section. For an annealing or a reaction of a CIGS precursor layer under an inert gas environment, the gas escaped from 210B may contain lots of Se vapors. If a formation of the CIGS absorber is required in a H₂S or H₂Se atmosphere, the escaped gas is very toxic, especially for the fatal H₂Se. The reaction gas is firstly controlled inside the reaction chambers. A pair of shutters 211A and 211B are installed between the unwinding chamber and the heating section S1 and between the winding chamber and the cooling section S2. During the reaction, they are closed to leave narrow slits for the roll movement. The width of these slits may be set from 1 to 10 mm, preferably around 2-4 mm. The inert gas with a positive pressure from 209A and 209B is introduced through these slits to avoid the toxic gas leaking into the unwinding and winding chambers. The escaped gas from the volve 207B is finally introduced to a treatment system. The chamber 206 is remained under a vacuum during the whole annealing or reaction process. It has two main functions. On one hand, it is a thermal insulation buffer space to resist too much heat released to the air and stabilize the temperature in the reaction chambers. Since the vacuum space blocks the heat transfer through a heat conduction and a thermal convection but not a thermal radiation, the more vacuum or insulation layers outside the chamber 206 may be necessary to obtain a better heat insulation. On the other hand, 206 is a protection chamber for any possible gas leaking from the main chamber because the leaked gas can be vacuumed and led to the chemical treatment system.

Step 6: Deposition of a CdS layer through a CBD reactor.

Through the previous steps, a CIGS absorber layer has been successfully prepared. The core component of a CIGS solar cell is a p-n junction generated at the interface of a CIGS p-type semiconductor and a CdS (or ZnS, In₂O₃, etc.) n-type semiconductor. A CdS layer has to be deposited onto the surface of the CIGS layer to form this p-n junction. In the present production line, this CdS layer is fabricated with a CBD reactor that is invented by the present inventor and submitted with a patent application publication number of US 2011/0256656 A1.

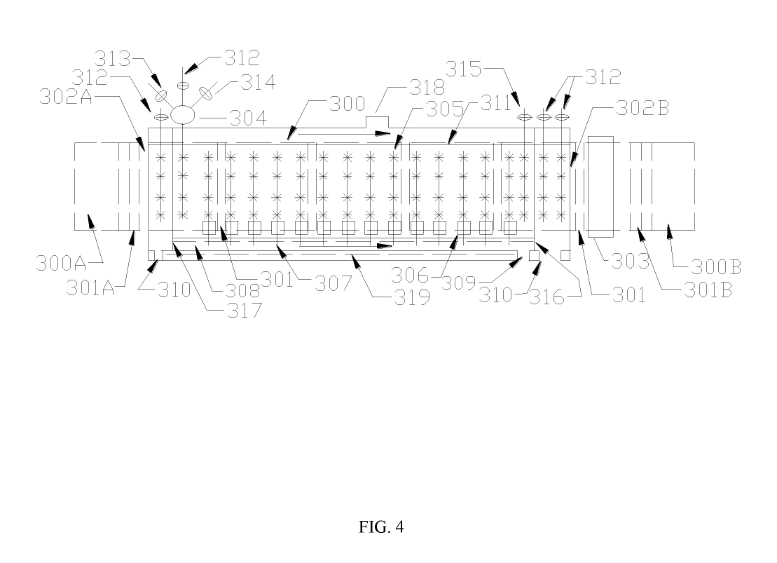

FIG. 4 shows the front view diagram for a presently invented apparatus. The flexible substrate 300 is loaded into an unwinding section as a roll 300A, vertically delivered through the entire reactor and ended as a product roll 300B in the winding section. 301A and 301B are guide rollers controlling the substrate movement. In particular, 301B should be combined with alignment and tension control capability, but the details are not drawn here. Between the rollers 301A and 301B, there are a series of idle rollers 301 inside the reactor chamber to hold the substrate vertically flat at correct positions. As shown in FIG. 4, the substrate and the rollers are drawn in dashed lines and the substrate surface to be deposited is facing back. The substrate is delivered from left to right along the arrow direction.

When the roll enters the reactor, it firstly passes a narrow slit on the left wall into the apparatus. Outside the narrow slit, are there a column of wind knifes 302A to gently blow preheated air into the chamber to avoid the atmosphere inside the chamber coming out. Similarly, a column of wind knifes 302B are arranged on the other side out of the chamber, as shown in FIG. 4. After the roll enters the chamber, it is firstly washed by preheated DI water introduced through the valve 312 and sprayed out of the spray nozzles 305. The DI water will cover the whole surface from the top to the bottom to clean the surface and wet it before CdS deposition. It also helps to heat the substrate to a reaction temperature. This DI water washing chamber has been separated from the main reaction chamber with a board 317. The waste water flows through a solution outlet 310 to exhaust without any special treatment.

The substrate then moves into the CBD deposition section. As illustrated in FIG. 4, there is a solution mixing vessel 304 on top of the reactor. Three solution inlets through the valves 312, 313 and 314. Valve 312 delivers the preheated DI water, Valve 313 carries one preheated reaction solution such as Cd²⁺ cation ammonia solution, and Valve 314 delivers another preheated solution such as thiourea solution. All of these three solutions are sprayed into the mixing vessel 304. This mixing vessel possesses a oval or pear shape. The sprayed solutions swirl down around the round internal wall and pass a small opening on the bottom of the vessel. During this process, the solutions have been well mixed in just a couple of seconds. The bottom opening of the vessel connected to a pipe 307 with some spray nozzles 305 to spray the mixed solution onto the substrate surface from the top to the bottom. This device carries preheated compressed air to help the solution spray, similar to a spray pyrolysis process. The preheated air helps to remain a constant temperature inside the reaction chamber.

When the freshly mixed solution is sprayed onto the substrate surface, [Cd(NH₃)₄]²⁺ and (NH₂)₂CS will start to adsorb and nucleate on the surface at an induction stage. The used solution flows down into a groove under the substrate and slowly flows to the right direction. Then this used solution is pumped up by a pump 306 and sprayed onto the substrate surface again through the pipe 307. In this case, the top end of the spray pipe is blocked and the solution is sprayed out with pressure out of the nozzles 305 from the top to the bottom. The reacted solution flows back to the groove again and is pumped up again with next pump, as illustrated in FIG. 4. With the substrate movement to the right direction, its surface is covered with the solutions pumped and sprayed from a series of the pump-spray pipe combinations. The substrate surface is continuously reacted from the freshly mixed solution to the gradually aged solution until end of the CBD process. The deposited layer will go through the induction and film growth processes to achieve a high quality thin film. During the whole CBD process, density of the pumps and the spray pipes should be arranged in a way of covering and wetting the full substrate surface. The length of the reaction chamber can be determined by the delivery speed and the reaction time. If a substrate delivery speed is 1 meter per minute and the reaction time is 10 minutes, for instance, a 10 meter long reaction chamber is necessary.

In FIG. 4, the dashed line 319 represents a series of heating elements underneath the solution groove 308. These heating elements can be fully program-controlled to heat the solution to a constant temperature. In front of the top edge of the substrate, there is a board 311 crossover the whole reaction chamber. It should be designed to block the solution from spraying to the backside. Although this may waste 1-2 cm top edge of the substrate, the edge is usually not useful to fabricate a solar cell. In back of the bottom edge of the substrate, there is a row of wind knifes crossover the whole chamber. It gently blows the preheated air to the back edge of the substrate to avoid the solution wetting onto the back edge. These top and bottom protection may remain the entire backside dry during the whole CBD process.

At the end of the reaction chamber as separated with a board 316, the substrate surface is washed with the used DI water through a valve 315. The DI water here has been used at the next rinsing stage but preheated before it is used in the reaction chamber. Also, the preheated compressed air may be used here to help spraying if necessary. The aged solution and this washing solution are combined here and flow out of the waste outlet 309 on the equipment bottom. This waste solution contains cadmium, sulfur, ammonium and other chemicals. It needs to be seriously treated.

When the substrate goes through the slit on a separation board 316 into the rinsing chamber, perhaps 99% of the residue of the reaction solution has been washed away in the previous washing stage. In this chamber, the substrate surface is further rinsed twice with clean DI water delivered through the valves 312 to make the deposited film totally clean. The rinsed water is collected through the water outlet 310 on the equipment bottom, and a part of it is reused to wash the substrate in the previous reaction chamber. The cleaned substrate is now travelling out of the reactor. When it goes through the slit in the end wall, it is pre-dried by the wind knifes 302B and further dried through a heating device 303 before it is winded as a product roll 300B in the winding section.

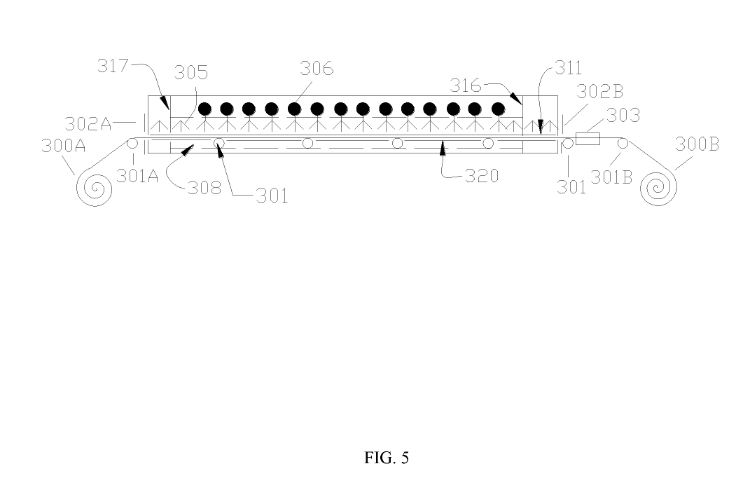

Within the reactor, the atmosphere is controlled at a constant temperature with the heating elements on the bottom and the preheated air, DI water and the solutions. The waste gas containing ammonium is exhausted through the top outlet 318. The whole process is further demonstrated in FIG. 5 as a top view. Here the workpiece roll and the rollers are more clearly illustrated. The wind knifes 302A and 302B are clearly shown. 320 is the row of wind knifes in back of the bottom edge of the substrate to avoid the solution wetting to the back edge of the substrate, as described above. The width of the aged solution groove 308 is illustrated as well.

More detailed information about this CBD reactor is described in the reference patented with a publication number of US 2011/0256656 A1 . Similarly, the detailed information about the electroplating information is shown in the reference of the patent application with an application number of Ser. No. 13/046,710, and the detailed information about the thermal reactor is presented in the other reference of the patent application numbered with Ser. No. 13/084,568.

Step 7: Transparent conductive oxides coated with a sputter.

The top window layer over the CdS is transparent conductive oxides (TCO) which include a highly resistive zinc oxide (ZnO) and a lowly resistive layer such as ITO or AZO. The equipment included in this step is a roll-to-roll sputter. This sputter has been separated into two main sections. The first section is to sputter ZnO film in and the second section is to sputter ITO or AZO film.

The substrate roll to be sputtered is firstly loaded into an unwinding chamber, delivered through the sputtering chambers that consist of a series of modular chambers, and finally ended inside a winding chamber. In the first sputtering section containing 2-6 targets of Zn or ZnO, the substrate surface is deposited with ZnO. In the second sputtering section containing 2-6 targets of ITO or AZO, the substrate surface is deposited with ITO or AZO window layer.

The sputtering speed depends on conductivity of a sputtered material. At present, a ZnO target is frequently selected to sputter ZnO in a thin film solar cell manufacture because it provides an uniform and consistent ZnO thin film. The sputtering process is easy to control with a ZnO target. The drawback is that the sputtering speed is significantly slow due to a high resistivity of the sputtered ZnO layer. In addition, the ZnO target is more expensive than a Zn target. Therefore, a reactive sputtering method with a Zn target in a highly concentrated oxygen atmosphere is selected in the present production line. With a metal target, the sputtering speed can be designed up to one meter per minute. During a sputtering process, Zn is sputtered and reacted with oxygen to form a ZnO thin film on the substrate surface. The sputtering chambers can be heated and a partial pressure of oxygen can be adjusted to obtain an optimal ZnO film.

The second section of the sputtering chambers is to deposit an ITO or AZO thin film. Because the sputtered materials possess a low resistivity, the substrate delivery speed can be achieved with a desirable rate such as one meter per minute. The sputtering chambers shall be equipped with a heating system to increase the adhesion of a resultant ITO film. Since the ITO or AZO sputtering requires a low oxygen partial pressure, a buffer chamber should be arranged between the ZnO and the ITO sputtering sections to turn the sputtering gases from an oxygen rich to an oxygen poor argon atmosphere. Similar to the sputter used in Step 2, this TCO sputter can be designed to work with a vertically or horizontally delivered substrate.

Step 8: Screen printing metallic finger and bus lines.

After all of the component layers are deposited, some metallic finger and bus lines have to be deposited onto the ITO surface. If the substrate materials are non-conductive, the metallic finger and bus lines may not be necessary because three steps of laser or mechanical scribing can be applied to avoid these metallic lines and significantly affect the following processes to fabricate modules. For a conductive substrate, however, a completed roll has to be cut into single cells after the finger and bus lines are deposited on the window surface according to predesigned cell models. These cells have to be cut and assembled into solar panels through a series of module fabrication processes.

Different methods can be used to deposit the finger and bus lines, such as vacuum coating, electrochemical deposition and screen printing. In the present production line, a screen print method is used to deposit these lines. Accordingly, a roll-to-roll screen printer is included in the present production line. This screen printer should be installed with an industrial scan camera to precisely detect printing positions. The printing ink is conductive silver paste which has to be dried through an UV or IR dryer after printing.

Step 9: Cell cut, measurement and sorting.

Now the solar cells have been successfully fabricated on a flexible substrate roll. The printed cells shall be cut into single cells. Some parameters of these solar cells have to be measured with a measurement system combined with a solar simulator and a measurement instrument. The measured solar cells are then sorted according to their conversion efficiencies to prepare for manufacture of solar modules.

One automatical hybrid system can be manufactured to complete all of the processes described above. The solar cell roll is installed into an unwinding device and delivered up to a cutting platform where the roll is sheared and cut into single cells with sharp metal knives. These cells are immediately picked up by a mechanical arm and then put under a single flash solar simulator to measure their parameters. The measured solar cells are immediately taken off by another mechanical arm and place into different boxes according to their conversion efficiency groups.

These procedures can also be operated with a couple of simple equipments. For example, the solar cells are cut with one cutting machine and then measured with another measurement system. With these combination, more manual operations have to be involved for cell picking and sorting.

In summary, the present production line provides an entire manufacture process and a series of equipments to fabricate CIGS thin film solar cells on the flexible substrates through a roll-to-roll or reel-to-reel process. Several core processes and the related equipments have been submitted for patent applications by the present inventor. With this production line, one can manufacture the CIGS solar cells from the starting substrate rolls to the completed solar cells via a roll-to-roll industrial process. It not only provides manufacture processes but also includes core apparatuses. The technology contained in the present production line can be used to manufacture inexpensive but high efficiency thin film solar cells that will possess high competitiveness in the global photovoltaic market.

What is claimed is:

1. A manufacture production line to fabricate CIGS thin film solar cells on conductive flexible substrate surfaces through a roll-to-roll process, comprising:
fabricating CIGS thin film solar cells from blank rolls of stainless steel or aluminum alloy foil to completed solar cells;
depositing molybdenum layer with a thickness from 100 to 1000 nm plus an accessory layer of niobium with a thickness from 5 to 200 nm, preferably 20-80 nm, with a sputtering method;
electroplating multiple layers of single copper, indium, gallium and/or selenium elements, their alloy and/or their combination thereof;
vacuum-evaporating selenium and a salt of sodium, potassium or lithium, including sodium fluorite, potassium fluorite, and lithium fluoride, on the surfaces of electroplated CIGS multiple layers;
annealing the CIGS multiple layers under an inert atmosphere and at a constant temperature between 450 and 650° C., preferably 500-600° C., to obtain a stoichiometric and homogeneous CIGS absorber layer;
depositing a cadmium or zinc sulfide layer as a buffer material above the CIGS layer through a CBD deposition method;
sputtering a zinc oxide layer (50-200 nm) and an indium tin oxides layer (50-200 nm) onto the surface of CdS layer;
screen-printing conductive silver paste on top of the window layer to form finger and bus lines;
cutting the completed rolls into single solar cells, measuring their conversion efficiencies and sorting the completed solar cells into different groups.

2. The production line of claim 1, wherein the electroplating apparatus is a modular one with a patent application number of Ser. No. 13/046,710, the thermal reactor to anneal the CIGS material is a modular one with a patent application number of Ser. No. 13/084568, and the CBD reactor to deposit CdS films is the one with a patent application publication number of US 2011/0256656 A1.

3. The manufacture methods associated with the apparatus in claim 2.

4. The production line of claim 1, wherein the substrates are continuous flexible stainless steel or aluminum alloy foil rolls with a thickness between 0.02 and 0.15 mm, preferably 0.04-0.08 mm, and a width between 100 and 2000 mm, preferably 300-1200 mm.

5. The production line of claim 1, wherein the substrate delivery speed is from 0.3 to 1.5 meters per minute, preferably one meter per minute.
